(19) United States
(12) Patent Application Publication
(10) Pub. No.: US 2025/0194323 A1
(43) Pub. Date: Jun. 12, 2025

(54) ADAPTER DEVICE FOR CHIP PACKAGING TEST

(71) Applicant: Jade Bird Display (Shanghai) Limited, Pudong New Area, Shanghai (CN)

(72) Inventors: Chenchao XU, Shanghai (CN); Yang YUE, Shanghai (CN)

(73) Assignee: Jade Bird Display (Shanghai) Limited, Pudong New Area, Shanghai (CN)

(21) Appl. No.: 18/846,218

(22) PCT Filed: Mar. 24, 2022
(86) PCT No.: PCT/CN2022/082769

§ 371 Date: Sep. 11, 2024

(51) Int. Cl. H10H 29/01; G01R 31/26; G01R 31/28

(52) U.S. Cl. CPC H10H 29/036; G01R 31/2635; G01R 31/2896

(57) ABSTRACT

An adapter device for chip packaging test is disclosed in the present disclosure. The adapter device for chip packaging test includes: a connection plate comprising a plurality of packaging testing units. Each packaging testing unit includes: a plate slot for accommodating a micro chip, a signal transmission sheet coupled with the plate slot, a signal connector coupled with the plate slot, and a chip substrate. In some embodiments, the adapter device for chip packaging test further includes: an adapter plate coupled with the connection plate through an inter-plate connection region included in the adapter plate. A method for chip packaging testing includes bonding a plurality of the micro chips to the chip substrates of the connection plate, coupling the connection plate with the adapter plate, inspecting the plurality of micro chips, and identifying a faulty micro chip using the identification code.

### TECHNICAL FIELD

The present disclosure relates generally to the technical field of testing for integrated circuit packaging, and more particularly, to an adapter device for chip packing test.

### BACKGROUND

Display technologies are becoming increasingly important in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices.

A Light-Emitting Diode (LED) chip generally includes an Organic Light-Emitting Diode (OLED) chip, a Mini Light-Emitting Diode (Sub-millimeter Light-Emitting Diode) chip or a Micro LED (Micro Meter Light-Emitting Diode) chip and the like. LED is widely applied in the field of illumination. As the LED display screen gradually permeates towards the high-end market, the quality requirement of the LED display screen device is higher.

The quality of the LED display chip packaging greatly affects the quality of the LED display screen device. When the packaging test is carried out, there are several issues to be solved at present, for example, how to improve the convenience of operation in each processing step of the packaging, how to integrate the repeating operations in each processing step, and improve the packaging efficiency, and how to quickly find the unqualified packaging chip according to the feedback result in the testing process so that the detection efficiency can be improved.

### SUMMARY

There is a need for improved display packaging designs that improve upon, and help to address the issues and shortcomings of conventional display packaging systems, such as those described above. In particular, there is a need for display panels with improved stability and reliability with better images.

To achieve the above objectives, in one aspect of some exemplary embodiments, the present disclosure provides an adapter device for chip packaging test, comprising: a connection plate comprising a plurality of packaging testing units. Each packaging testing unit includes: a plate slot for accommodating a micro-chip, a signal transmission sheet coupled with the plate slot, a signal connector coupled with the plate slot, and a chip substrate.

In some exemplary embodiments or any combination of preceding exemplary embodiments, the adapter device for chip packaging test further includes: an adapter plate coupled with the connection plate through an inter-plate connection region included in the adapter plate,

In some exemplary embodiments or any combination of preceding exemplary embodiments of the adapter device for chip packaging test, the adapter plate further includes: a corresponding connector to couple with the signal connector of the connection plate.

In some exemplary embodiments or any combination of preceding exemplary embodiments of the adapter device for chip packaging test, the connection plate is a flexible printed circuit (FPC) plate.

In some exemplary embodiments or any combination of preceding exemplary embodiments of the adapter device for chip packaging test, the connection plate has a horizontal dimension of 70 mm-90 mm, and a vertical dimension of 40 mm-50 mm.

In some exemplary embodiments or any combination of preceding exemplary embodiments of the adapter device for chip packaging test, the connection plate has a thickness of 0.2 mm-0.6 mm.

In some exemplary embodiments or any combination of preceding exemplary embodiments of the adapter device for chip packaging test, the signal transmission sheet is an FPC board containing data transmission lines.

In some exemplary embodiments or any combination of preceding exemplary embodiments of the adapter device for chip packaging test, a first end of the signal transmission sheet is integrally formed with an upper portion of the plate slot and is clamped in the signal connector.

In some exemplary embodiments or any combination of preceding exemplary embodiments of the adapter device for chip packaging test, a second end of the signal transmission sheet is connected to an electrical connection end of the chip substrate.

In some exemplary embodiments or any combination of preceding exemplary embodiments of the adapter device for chip packaging test, a front surface of the signal connector includes a flash memory chip packaged in a shielded enclosure.

In some exemplary embodiments or any combination of preceding exemplary embodiments of the adapter device for chip packaging test, a surface of the shielded enclosure has a plurality of pin holes.

In some exemplary embodiments or any combination of preceding exemplary embodiments of the adapter device for chip packaging test, a surface of the signal connector has a protruding connector.

In some exemplary embodiments or any combination of preceding exemplary embodiments of the adapter device for chip packaging test, a surface of the chip substrate is made of an iron-nickel alloy.

In some exemplary embodiments or any combination of preceding exemplary embodiments of the adapter device for chip packaging test, the plate slot accommodates a micro-LED chip and has a corresponding size according to the micro-LED chip.

In some exemplary embodiments or any combination of preceding exemplary embodiments of the adapter device for chip packaging test, a diameter of the plate slot is less than 6 μm.

In some exemplary embodiments or any combination of preceding exemplary embodiments of the adapter device for chip packaging test, the connection plate includes an identification code on a surface of the connection plate.

In some exemplary embodiments or any combination of preceding exemplary embodiments of the adapter device for chip packaging test, the identification code is a two-dimensional code.

In some exemplary embodiments or any combination of preceding exemplary embodiments of the adapter device for chip packaging test, the corresponding connector is a recessed connector.

In some exemplary embodiments or any combination of preceding exemplary embodiments of the adapter device for chip packaging test, the adapter plate includes a plurality of device connectors configured to attach to a vacuum suction table for packaging testing.

In some exemplary embodiments or any combination of preceding exemplary embodiments of the adapter device for chip packaging test, the connection plate includes a plurality of through holes and cross marks.

In some exemplary embodiments or any combination of preceding exemplary embodiments of the adapter device for chip packaging test, the connection plate includes a plurality of positioning holes configured to connect to a machine table for packaging testing.

In some exemplary embodiments or any combination of preceding exemplary embodiments of the adapter device for chip packaging test, the adapter plate includes a plurality of positioning pin holes.

In some exemplary embodiments or any combination of preceding exemplary embodiments of the adapter device for chip packaging test, a micro-LED display chip is integrated on the chip substrate by Die Bonding and Wire Bonding.

In another aspect of some exemplary embodiments, the present disclosure provides a method for chip packaging testing, comprising: providing a connection plate comprising an identification code and a plurality of packaging testing units; bonding a plurality of the micro chips to the chip substrates of the connection plate; providing an adapter plate; coupling the connection plate with the adapter plate; inspecting the plurality of micro chips; and identifying a faulty micro chip using the identification code. In some embodiments, each packaging testing unit includes: a plate slot for accommodating a micro chip, a signal transmission sheet coupled with the plate slot, a signal connector coupled with the plate slot, and a chip substrate.

In some exemplary embodiments or any combination of preceding exemplary embodiments of the method for chip packaging testing, the micro chip is a micro-LED display chip.

In some exemplary embodiments or any combination of preceding exemplary embodiments of the method for chip packaging testing, inspecting the plurality of micro chips includes inspecting a light-emitting condition of the micro-LED display chips.

In some embodiments of the present disclosure, the systems and methods disclosed herein greatly improve the efficiency of chip packaging, in particular, the systems and methods improve the convenience of operation in each processing step of the packaging, integrate the repeating operations in each processing step, and improve the packaging efficiency, and further improve the detection efficiency by quickly finding the unqualified packaging chip according to the feedback result in the testing process.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

For convenience, “up” is used to mean away from the substrate of a light emitting structure, “down” means toward the substrate, and other directional terms such as top, bottom, above, below, under, beneath, etc. are interpreted accordingly.

FIG. 1 is a schematic diagram of an exemplary connection plate of a chip packaging testing adapter device according to some embodiments of the present disclosure.

FIG. 2 is a schematic diagram of a back surface of an exemplary connection plate of a chip packaging testing adapter device according to some embodiments of the present disclosure.

FIG. 3 is a schematic diagram of an exemplary adapter plate of a chip packaging testing adapter device according to some embodiments of the present disclosure.

FIG. 4 is a schematic diagram of an exemplary adapter device for chip packaging testing according to some embodiments of the present disclosure.

FIG. 5 is a schematic diagram of a flow chart of an exemplary method of a chip packaging testing according to some embodiments of the present disclosure.

The Figures include the following identifications of parts: 1 connection plate, 2 plate slot, 3 signal transmission sheet, 4 a flash memory chip (and/or signal connector), 5 chip substrate, 6 adapter plate, 7 inter-plate connection region, 8 protruding connector, 9 recessed connector, 10 device connector, 11 through hole, 12 cross mark, 13 positioning pin hole, 14 positioning hole, 15 identification code, and 16 adapter device,

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

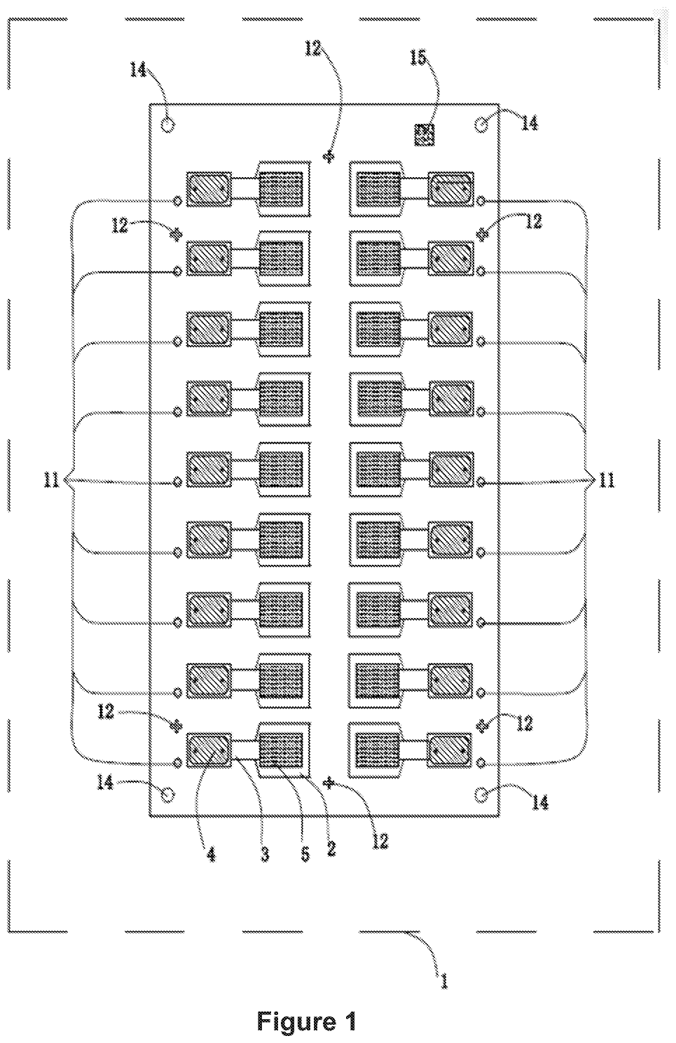

FIG. 1 is a schematic diagram of an exemplary connection plate of a chip packaging testing adapter device according to some embodiments of the present disclosure.

In some embodiments, the system disclosed herein, for example, a chip packaging testing adapter device, at least comprises: a connection plate and an adapter plate. The connection plate is used for connecting and supporting the micro LED package. The adapter plate is used for connecting the connection plate. The signal connection pads of the adapter plate are electrically connected to the signal connection pads of the connection plate, for example, through the device connector on the adapter plate, and the signal connector on the connection plate.

In some embodiments, the micro LED package comprises: a micro LED panel, a signal transmission sheet, a flash memory chip (and/or signal connector), a protruding connector, and a chip substrate. In some embodiments, the micro LED panel is positioned on the end of the signal transmission sheet and opposite to (or on) the chip substrate.

In some embodiments, as shown in FIG. 1, the connection plate (1) is an FPC (flexible printed circuit) plate. The horizontal dimension of the connection plate (1) is 70 mm-90 mm, specifically, the size can be 70 mm, 80 mm, or 90 mm, the vertical dimension is 40-50 mm, specifically, the size can be 40 mm, 44 mm, 46 mm, 48 mm, or 50 mm, and the thickness is 0.2 mm-0.6 mm, specifically, the size can be 0.2 mm, 0.4 mm or 0.6 mm. A plurality of plate slots (2) are formed in the connection plate (1). In general, the plurality of plate slots (2) form a slot array. And in each plate slot (2), the signal transmission sheet (3) is usually an FPC board containing data transmission lines and the signal transmission sheet (3) has the same material as that of the connection plate (1), One end of the signal transmission sheet (3) is integrally formed with the upper/surface portion of the plate slot (2) and is clamped in the signal connector (4). The front surface of the signal connector (4) is a flash memory chip packaged in a shielded enclosure. In some embodiments, the enclosure is made of the white copper material. And a plurality of pin holes are formed on the surface of the shielded enclosure and used for the hot air flow entering when performing SMT (surface mounting technology). The four corners of the shielded enclosure are used for heat dissipation of the flash memory chip.

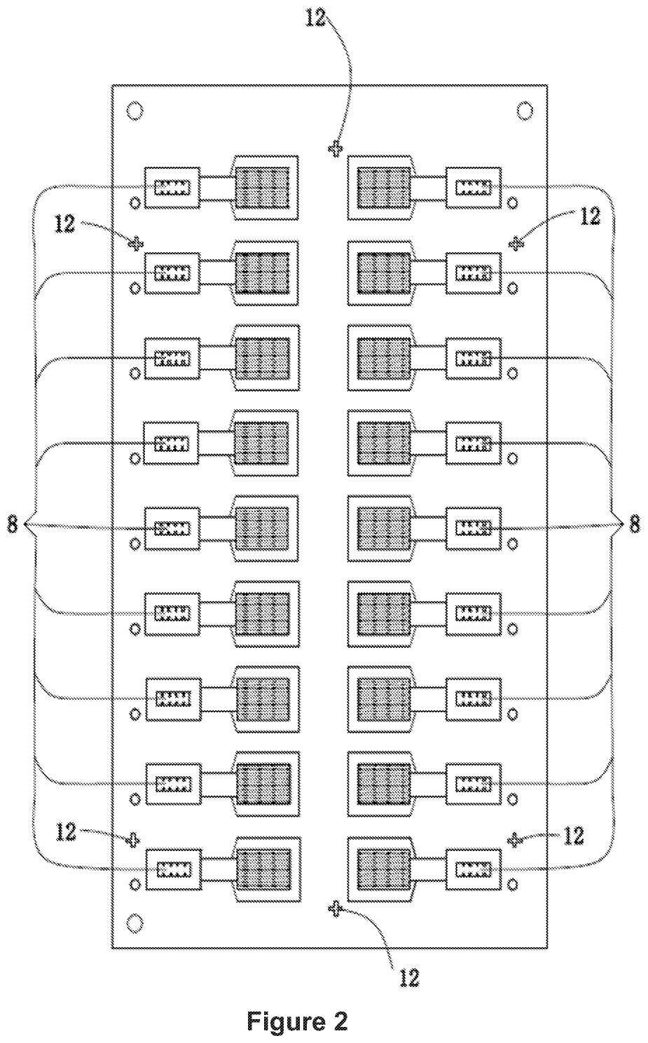

FIG. 2 is a schematic diagram of a back surface of an exemplary connection plate of a chip packaging testing adapter device according to some embodiments of the present disclosure.

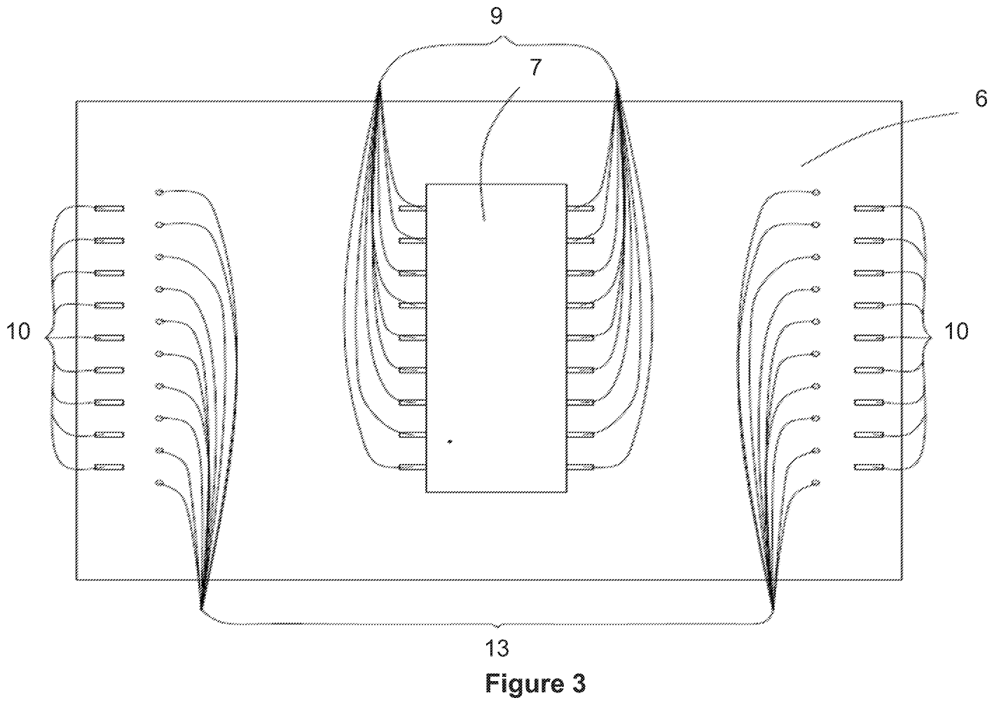

FIG. 3 is a schematic diagram of an exemplary adapter plate of a chip packaging testing adapter device according to some embodiments of the present disclosure.

As shown in FIG. 2, the back surface of the signal connector (4) has a protruding connector (8) which is used for inter-plate connection with the adapter plate (6) as shown in FIG. 3. As shown in FIG. 1, the other end of the signal transmission sheet (3) is connected to the electrical connection end of the chip substrate (5). The surface of the chip substrate (5) is made of an iron-nickel alloy. The size of the plate slot (2) is related to the chip size in the packaging test, and the chip in the packaging test is usually a micro-LED chip or an OLED chip, or both. When the chip in the packaging test is a Micro LED chip, the diagonal dimensions of the micro-LED chips are respectively 0.13 inch, 0.22 inch, and 0.31 inch, the resolutions are respectively 1280×720 P, 1920×1080 P, and 640×480 P, the pixel pitches are respectively 5 μm, 2.5 μm, and 4 μm. The size of the plate slot (2) will vary according to the above-mentioned diagonal dimensions. In some embodiments, an identification code (15) is provided on one surface of the connection plate (1). The identification code (15) is used to quickly find out the unqualified chip according to the feedback result. The identification code (15) comprises a two-dimensional code, a bar code, etc. The connection plate (1) and the signal transmission sheet (3) may also be PCBs.

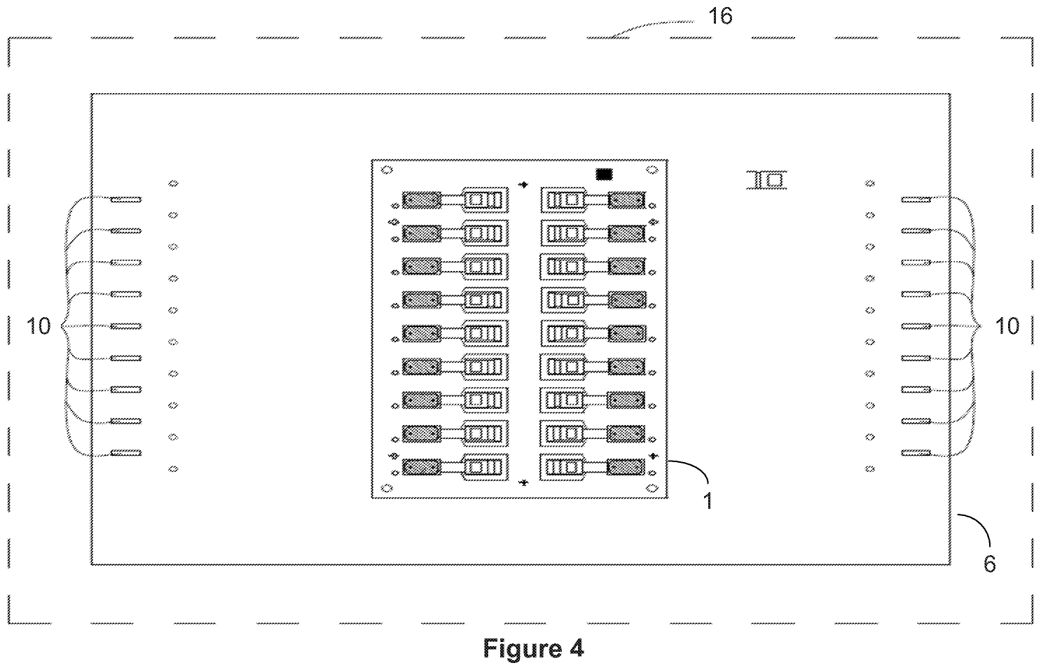

As shown in FIG. 3, an adapter plate (6) of an adapter device is provided for a chip packaging test. An adapter plate (6) is a PCB (Printed Circuit Board) plate. An opening is formed in the adapter plate (6) and is matched with the size of the connection plate (1). The opening region is the inter-plate connection region (7). It allows the connection plate (1) to be embedded in the adapter plate (6) through a plate connector. There are recessed connectors (9) on both sides of an inter-plate connection region (7) for plate connection. As shown in FIG. 2, for inter-plate connection, a recessed connector (9) is used to connect with the protruding connector (8) on the back surface of a signal connector (4), to make a connection plate (1) connected with an adaptor plate (6). The connectors for the BTB (Board To Board) connection are protruding connectors (8) and recessed connectors (9). In some embodiments, the connectors are not limited to protruding connectors (8) and recessed connectors (9) and may be other types of connector pairs to secure the connection between the connection plate (1) and the adapter plate (6). For example, connectors (8) on the back of the signal connector (4) can be recessed connectors and connectors (9) on the adapter plate (6) can be protruding connectors. A device connector (10) is provided in an adapter plate (6), and in some examples, a device connector (10) is a through hole. A device connector (10) and the signal transmission sheet (3) in a plate slot (2) as shown in FIG. 1, make an adaptor device (16) as shown in FIG. 4 attach to a vacuum suction table of the packaging test device, together with the hollowed-out region etched after the cutting process. In some embodiments, the connected connection plate (1) and adapter plate (6) were grasped by a mechanical hand and placed precisely on a vacuum suction table for metallurgy process. A plurality of holes of the vacuum suction table are aligned with the LED packages or the connected connection plate (1) and adapter plate (6) for vacuum suction. In some embodiments, laser is used to cut out an area along the predefined outline of some connection points on the connection plate (1). The hollowed-out region is the remaining region aside from the area formed by the connection points. The adapter plate (6) may also be a FPC plate.

In an optional example, as shown in FIG. 1, the peripheral side of the plate slot array of the connection plate (1) is provided with a plurality of through holes (11) and cross marks (12). The aperture of a through hole (11) is between 1 mm and 2 mm, specifically 1 mm, 1.5 mm, 2 mm. The cross mark (12) is located on the front and back surfaces of a connection plate (1) as shown in FIGS. 1 and 2, and they are used for aligning the plate slots (2) on a connection plate (1) in a packaging test.

In an optional example, as shown in FIG. 1, the four corners of the connection plate (1) further include a positioning hole (14). The positioning hole (14) is a through hole. The diameter of the positional hole (14) is 2 mm-3 mm, specifically 2 mm, 2.5 mm, and the 3 mm. A connection plate (1) may be directly connected to the machine table of the packaging test device through the positioning holes (14), without using an adapter plate (6).

In an optional example, as shown in FIG. 3, two sides of the adapter plate (6) further include positioning pin holes (13) for the packaging test device to perform coarse alignment on the plate slots (2). In some embodiments, the positioning pin holes (13) are further located within the inter-plate connection region (7) of the adapter plate (6). In some embodiments, the coarse alignment is to align the positioning pin holes (13) of the adapter plate (6) with the through holes (11) of the connection plate. In some examples, positioning pin holes (13) are through holes. When the inter-plate connection is realized with pin connections through positioning pin holes (13), the number of pins is usually 6-20. Usually, the number of pins is related or corresponding to the number of data transmission lines in the signal transmission sheets (3) as shown in FIG. 1.

FIG. 4 is a schematic diagram of an exemplary adapter device for chip packaging testing according to some embodiments of the present disclosure.

In some embodiments, the adapter device (16) includes the connection plate (1) as shown in FIGS. 1 and 2, and the adapter plate (6) in FIG. 6. The connection plate (1) is coupled with the adapter plate (6). In one example, as shown in a schematic diagram of the adapter device (16) of the present disclosure in FIG. 4, after a micro-LED display chip is adhered to the adapter device (16), the light-emitting condition of the micro-LED display chip needs to be inspected. When the micro-LED display chip in the test is found to be unable to adjust the display color difference by means of compensation, the test device quickly finds out the tested chip by means of the identification code (15) on the connection plate (1) for subsequent processing. In some embodiments, the panels/LED packages on the connection plate (1) have a certain order, and the ID and the location information of each panel/LED package are related. And the relationships can be identified by the location information of the identification code (15). The adapter device (16) can place or integrate a certain number of micro-LED display chips on the chip substrate (5) of a connection plate (1), so as to reduce the magnitude of the repeated steps in existing technologies, of placing the micro LED display chips one by one into the testing machine for illumination. It can quickly locate the target chips by means of the identification code (15) provided on the connection plate (1), thereby significantly improving the test efficiency.

In one example, after performing feeding detection on the connection plate (1) as shown in FIG. 1, the packaging device first performs a DB (Die Bonding) operation on the micro-LED display chip dies on the connection plate (1) pinned with 18 chip substrates (5), and then performs a WB (Wire Bonding) operation on the micro-LED display chips on the connection plate (1) after the DB operation. In some embodiments, DB is a manufacturing process used in the packaging of semiconductors. In the DB process, a die (or chip) is first picked from a wafer or waffle pack and is then placed at a specific location on the substrate by attaching the die (or chip) to the substrate or package by epoxy or solder. In some embodiments, WB is a device fabrication and packaging process of making interconnections between an integrated circuit (IC) or other semiconductor device and its packaging. In some examples, WB can be used to connect an IC to other electronics or to connect one printed circuit board (PCB) to another. By integrating a certain number of chip substrates (5) on a connection plate (1), the magnitude of the repeated steps is greatly reduced in existing packaging technologies of performing DB operations and WB operations one by one in the die bonding and wire bonding process respectively. The method and system disclosed herein can quickly locate the faulty chips in the packaging process through the identification code (15) on the connection plate (1), thereby significantly improving the packaging efficiency.

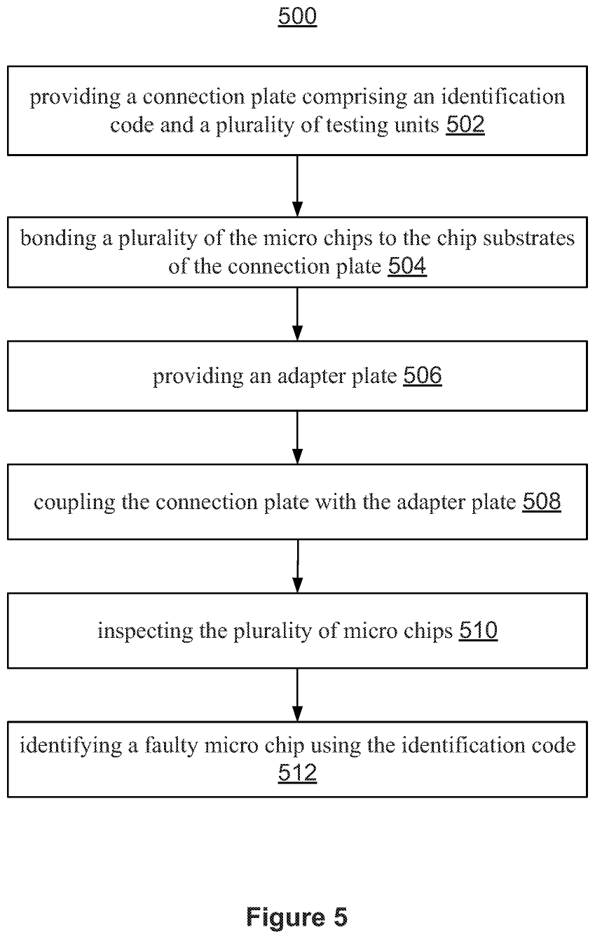

FIG. 5 is a schematic diagram of a flow chart of an exemplary method of a chip packaging testing 500 according to some embodiments of the present disclosure.

In some embodiments, a method for chip packaging testing, comprising; providing a connection plate comprising an identification code and a plurality of packaging testing units (502); bonding a plurality of the micro chips to the chip substrates of the connection plate (504); providing an adapter plate (506); coupling the connection plate with the adapter plate (508); inspecting the plurality of micro chips (510); and identifying a faulty micro chip using the identification code (512). In some embodiments, each packaging testing unit includes: a plate slot for accommodating a micro chip, a signal transmission sheet coupled with the plate slot, a signal connector coupled with the plate slot, and a chip substrate.

In the packaging process, the operation convenience in each process step is improved, the process of repeated operations in each process step are integrated, and the packaging efficiency is remarkably improved. In the test process, unqualified/faulty packaging chips can be quickly found according to the feedback test results, and the detection efficiency is greatly improved.

It is understood by those skilled in the art that, the chip packing testing adapter device is not limited by the structure mentioned above, and may include more or less components than those as illustrated, or some components may be combined, or a different component may be utilized.

It is understood by those skilled in the art that, all or part of the steps for implementing the foregoing embodiments may be implemented by hardware, or may be implemented by a program which instructs related hardware. The program may be stored in a flash memory, in a conventional computer device, in a central processing module, in an adjustment module, etc.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

Further embodiments also include various subsets of the above embodiments including embodiments as shown in FIGS. 1-5 combined or otherwise re-arranged in various other embodiments.

Although the detailed description contains many specifics, these should not be construed as limiting the scope of the disclosure but merely as illustrating different examples and aspects of the disclosure. It should be appreciated that the scope of the disclosure includes other embodiments not discussed in detail above. For example, the approaches described above can be applied to the integration of functional devices other than LEDs and OLEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present disclosure can be implemented in, using, or with the assistance of a computer program product, such as a storage medium (media) or computer readable storage medium (media) having instructions stored thereon/in which can be used to program a processing system to perform any of the features presented herein. The storage medium can include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present disclosure can be incorporated in software and/or firmware for controlling the hardware of a processing system, and for enabling a processing system to interact with other mechanisms utilizing the results of the present disclosure. Such software or firmware may include, but is not limited to, application code, device drivers, operating systems, and execution environments/containers.

It will be understood that, although the terms “first,” “second,” etc. may be used herein to describe various elements or steps, these elements or steps should not be limited by these terms. These terms are only used to distinguish one element or step from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art to best utilize the disclosure and the various embodiments.

1. An adapter device for chip packaging test, comprising:
a connection plate comprising a plurality of packaging testing units, each packaging testing unit including:
a plate slot for accommodating a micro chip,
a signal transmission sheet coupled with the plate slot,
a signal connector coupled with the plate slot, and
a chip substrate; and
an adapter plate coupled with the connection plate through an inter-plate connection region included in the adapter plate.

2. The adapter device for chip packaging test according to claim 1, wherein the adapter plate further includes: a plurality of connectors to couple with the plurality of corresponding signal connectors of the connection plate.

3. The adapter device for chip packaging test according to claim 1, wherein the connection plate is a flexible printed circuit (FPC) plate.

4. The adapter device for chip packaging test according to claim 1, wherein the connection plate has a horizontal dimension of 70 mm-90 mm, and a vertical dimension of 40 mm-50 mm.

5. The adapter device for chip packaging test according to claim 1, wherein the connection plate has a thickness of 0.2 mm-0.6 mm.

6. The adapter device for chip packaging test according to claim 1, wherein the signal transmission sheet is an FPC board containing data transmission lines.

7. The adapter device for chip packaging test according to claim 1, wherein a first end of the signal transmission sheet is integrally formed with an upper portion of the plate slot and is clamped in the signal connector.

8. The adapter device for chip packaging test according to claim 7, wherein a second end of the signal transmission sheet is connected to an electrical connection end of the chip substrate

9. The adapter device for chip packaging test according to claim 1, wherein a front surface of the signal connector includes a flash memory chip packaged in a shielded enclosure.

10. The adapter device for chip packaging test according to claim 1, wherein a surface of the shielded enclosure has a plurality of pin holes.

11. The adapter device for chip packaging test according to claim 1, wherein a surface of the signal connector has a protruding connector.

12. The adapter device for chip packaging test according to claim 1, wherein a surface of the chip substrate is made of an iron-nickel alloy.

13. The adapter device for chip packaging test according to claim 1, wherein the plate slot accommodates a micro-LED chip and has a corresponding size according to the micro-LED chip.

14. The adapter device for chip packaging test according to claim 1, wherein a diameter of the plate slot is less than 6 μm

15. The adapter device for chip packaging test according to claim 1, wherein the connection plate includes an identification code on a surface of the connection plate.

16. The adapter device for chip packaging test according to claim 15, wherein the identification code is a two-dimensional code.

17. The adapter device for chip packaging test according to claim 2, wherein the plurality of connectors of the adapter plate are recessed connectors.

18. The adapter device for chip packaging test according to claim 1, wherein the adapter plate includes a plurality of device connectors to attach to a vacuum suction table for packaging testing.

19. The adapter device for chip packaging test according to claim 1, wherein the connection plate includes a plurality of through holes and a plurality of cross marks.

20. The adapter device for chip packaging test according to claim 1, wherein the connection plate includes a plurality of positioning holes to connect to a machine table for packaging testing.

21. The adapter device for chip packaging test according to claim 1, wherein the adapter plate includes a plurality of positioning pin holes.

22. The adapter device for chip packaging test according to claim 1, wherein a micro-LED display chip is integrated on the chip substrate by Die Bonding and Wire Bonding

23. A method for chip packaging testing, comprising:
providing a connection plate comprising an identification code and a plurality of packaging testing units, each packaging testing unit including:
a plate slot for accommodating a micro chip,
a signal transmission sheet coupled with the plate slot,
a signal connector coupled with the plate slot, and
a chip substrate;
bonding a plurality of the micro chips to the chip substrates of the connection plate;
providing an adapter plate;
coupling the connection plate with the adapter plate;
inspecting the plurality of micro chips; and
identifying a faulty micro chip using the identification code.

24. The method for chip packaging testing according to claim 23, wherein the micro chip is a micro-LED display chip.

25. The method for chip packaging testing according to claim 24, wherein inspecting the plurality of micro chips includes inspecting a light-emitting condition of the micro-LED display chips.

26. The method for chip packaging testing according to claim 23, wherein the connection plate is a flexible printed circuit (FPC) plate.

27. The method for chip packaging testing according to claim 23, wherein the adapter plate further includes a plurality of connectors to couple with the plurality of corresponding signal connectors of the connection plate.
